(19) United States
(12) Patent Application Publication
(10) Pub. No.: US 2026/0239566 A1
(43) Pub. Date: Aug. 13, 2026

(54) LIQUID COOLING MODULE AND RELATED DATA STORAGE ASSEMBLY

(71) Applicant: Wiwynn Corporation, New Taipei City (TW)

(72) Inventors: Ting-Ya Liao, New Taipei City (TW); Kang-Bin Mah, New Taipei City (TW); Kun-Hsien Lee, New Taipei City (TW)

(73) Assignee: Wiwynn Corporation, New Taipei City (TW)

(21) Appl. No.: 19/385,102

(22) Filed: Nov. 10, 2025

Related U.S. Application Data
(60) Provisional application No. 63/757,335, filed on Feb. 12, 2025.

(30) Foreign Application Priority Data
Aug. 27, 2025 (TW) 114132665

(51) Int. Cl. H05K 7/20; H05K 7/14

(52) U.S. Cl. CPC H05K 7/20272; H05K 7/1489; H05K 7/20781

(57) ABSTRACT

A liquid cooling module and a related data storage assembly are provided. The liquid cooling module is configured to cool a heat generating component. The liquid cooling module includes an inlet, an outlet and a casing. The inlet is for inputting a liquid coolant. The outlet is for outputting the liquid coolant. The casing includes a first sub-casing and a second sub-casing. The first sub-casing and the second sub-casing are connected to each other to jointly define a cavity. The cavity communicates with the inlet and the outlet for allowing the liquid coolant to flow therethrough. The cavity is formed in a meandering shape. Both the first sub-casing and the second sub-casing are formed in meandering shapes, so as to define a heat dissipation space external to the casing for accommodating the heat generating component.

### CROSS REFERENCE TO RELATED APPLICATIONS

This application claims the benefit of U.S. Provisional Application No. 63/757,335, filed on February 12th, 2025. The content of the application is incorporated herein by reference.

### BACKGROUND OF THE INVENTION

### 1. Field of the Invention

The present invention relates to a liquid cooling product, and more specifically, to a liquid cooling module having enhanced heat dissipation efficiency and improved space utilization, and a related data storage assembly.

### 2. Description of the Prior Art

With the increasing demand for high-performance computing systems and artificial intelligence applications, liquid cooling solutions have gradually replaced air cooling solutions and become a mainstream trend because the liquid cooling solutions provide higher heat dissipation efficiency. However, when integrating a liquid cooling system into an electronic device or a server, it is not only to ensure effective heat dissipation but also to optimize the utilization of internal space. Accordingly, it has become an important topic in the field to achieve both high heat dissipation efficiency and improved space utilization within a limited mechanical space.

### SUMMARY OF THE INVENTION

Therefore, it is an objective of the present invention to provide a liquid cooling module and a related data storage assembly that can meet the need of enhanced heat dissipation efficiency and improved overall space utilization, to solve the aforementioned problems.

The present invention discloses a liquid cooling module for cooling at least one heat generating component. The liquid cooling module includes an inlet, an outlet and a casing. The inlet is for inputting a liquid coolant. The outlet is for outputting the liquid coolant. The casing includes a first sub-casing and a second sub-casing. The first sub-casing and the second sub-casing are connected to each other to jointly define a cavity. The cavity communicates with the inlet and the outlet for allowing the liquid coolant to flow therethrough, and the cavity is formed in a meandering shape. Both the first sub-casing and the second sub-casing are formed in meandering shapes, so as to define at least one heat dissipation space external to the casing for accommodating the at least one heat generating component.

The present invention further discloses a data storage assembly. The data storage assembly includes a tray, at least one heat generating component and the liquid cooling module as described above. The liquid cooling module is disposed within the tray and configured to cool the at least one heat generating component.

The liquid cooling module and the related data storage assembly achieve the following technical effects: (1) the casing of the liquid cooling module is formed in a meandering shape, so as to define the at least one heat dissipation space external to the casing for accommodating the at least one heat generating component, thereby improving space utilization and equipment density; (2) each heat dissipation space provides multiple contact surfaces for one heat generating component, thereby increasing heat dissipation area and improving heat dissipation efficiency; (3) each heat generating component is inserted into one heat dissipation space, thereby facilitating assembly and enhancing structural robustness; and (4) the dimension of the heat dissipation space can be designed based on the standard specifications of the heat generating component, thereby enabling interchangeability and compatibility.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective diagram of a data storage assembly with a partial enlargement according to an embodiment of the present invention.

FIG. 2 is an exploded diagram of the data storage assembly according to the embodiment of the present invention.

FIG. 3 is a perspective diagram of a liquid cooling module according to the embodiment of the present invention.

FIG. 4 is an exploded diagram of the liquid cooling module according to the embodiment of the present invention.

FIG. 5 is a sectional diagram of the liquid cooling module according to the embodiment of the present invention.

FIG. 6 is a sectional diagram of a liquid cooling module according to another embodiment of the present invention.

### DETAILED DESCRIPTION

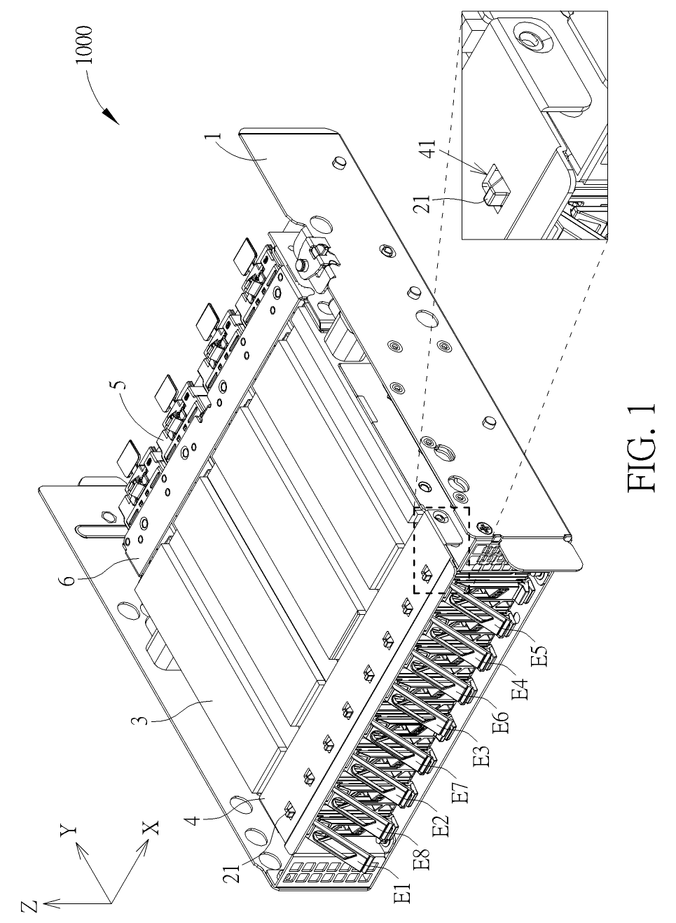

Please refer to FIG. 1, which is a perspective diagram of a data storage assembly 1000 with a partial enlargement according to an embodiment of the present invention. The data storage assembly 1000 includes a tray 1, at least one heat generating component (e.g. heat generating components E1 to E8), and a liquid cooling module 3. The liquid cooling module 3 is disposed within the tray 1 and configured to cool the heat generating components E1 to E8. The heat generating components E1 to E8 are arranged along a first direction X and respectively accommodated within heat dissipation spaces defined by the liquid cooling module 3. In this embodiment, the heat generating components E1 to E8 can be solid-state drives or other electronic devices. However, the type, the number and the sequential arrangement of the heat generating components are not limited to the embodiment illustrated in FIG. 1 and can be designed depending on practical demands. In another embodiment, at least one of the heat generating components E1 to E8 can be replaced with a non-heat generating component, such as a dummy component.

The data storage assembly 1000 further includes a first bracket 4, a docking board 5 and a second bracket 6. The first bracket 4 is disposed adjacent to a first side (e.g., a front side) of the liquid cooling module 3. Two ends of the first bracket 4 are connected to the tray 1 for fixing the liquid cooling module 3 and the heat generating components E1 to E8 onto the tray 1. The docking board 5 is disposed adjacent to a second side (e.g., a rear side) of the liquid cooling module 3 opposite to the first side of the liquid cooling module 3. The docking board 5 is connected to the heat generating components E1 to E8 for providing power and signal transmission to the heat generating components E1 to E8. The second bracket 6 is disposed adjacent to the second side of the liquid cooling module 3. Two ends of the second bracket 6 are connected to the tray 1 for fixing the liquid cooling module 3 and the docking board 5 onto the tray 1.

Specifically, the first bracket 4 and the second bracket 6 are two U-shaped brackets. A middle portion of the first bracket 4 and a middle portion of the second bracket 6 are configured to abut against the first side and the second side of the liquid cooling module 3, respectively. The two ends of the first bracket 4 and the two ends of the second bracket 6 can be fixed onto the tray 1 by corresponding fastening components, such as screws. The heights of the middle portions of the first bracket 4 and the second bracket 6 along a second direction Z are less than the height of the liquid cooling module 3 in the second direction Z, thereby preventing the liquid cooling module 3 from sliding out of the tray 1 along a third direction Y.

In an embodiment, as shown in the enlarged diagram, each of the heat generating components E1 to E8 includes at least one engaging hook 21. At least one engaging slot 41 is formed on the first bracket 4 and configured to engage with the corresponding engaging hook 21. As such, when the heat generating components E1 to E8 are inserted into the heat dissipation spaces of the liquid cooling module 3 from the front side, the engagement between the engaging slots 41 and the engaging hooks 21 ensures that the heat generating components E1 to E8 are properly mated with the docking board 5 at the rear side, and prevents unintentional disengagement of the heat generating components E1 to E8 from the liquid cooling module 3. In another embodiment, the engaging hook 21 can be replaced with a protruding column, a resilient clip and the like, which is not limited.

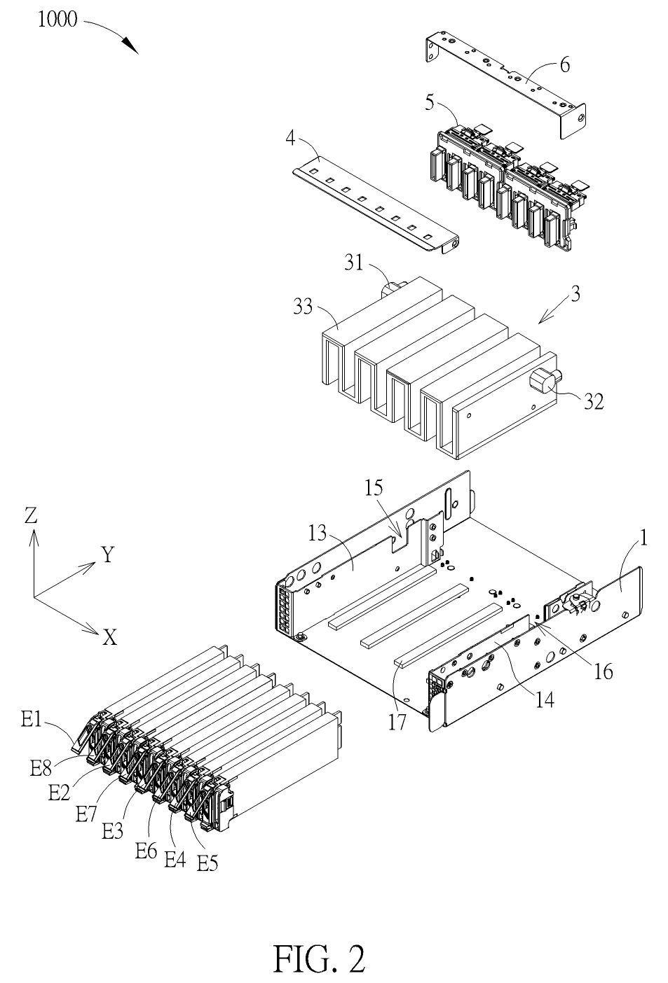

Please refer to FIG. 2, which is an exploded diagram of the data storage assembly 1000 according to the embodiment of the present invention. The data storage assembly 1000 further includes a third bracket 13 and a fourth bracket 14. The third bracket 13 is disposed adjacent to a third side (e.g., a left side) of the liquid cooling module 3. An end of the third bracket 13 is fixed onto a lateral wall of the tray 1, and the other end of the third bracket 13 is fixed onto a bottom portion of the tray 1. The fourth bracket 14 is disposed adjacent to a fourth side (e.g., a right side) of the liquid cooling module 3. An end of the fourth bracket 14 is fixed onto another lateral wall of the tray 1, and the other end of the fourth bracket 14 is fixed onto the bottom portion of the tray 1. Moreover, an end of the first bracket 4 and one end of the second bracket 6 are fixed onto the third bracket 13, and the other end of the first bracket 4 and the other end of the second bracket 6 are fixed onto the fourth bracket 14. In other words, the first bracket 4 and the second bracket 6 are fixed onto the tray 1 via the third bracket 13 and the fourth bracket 14. Furthermore, a first groove 15 and a second groove 16 are formed on the third bracket 13 and the fourth bracket 14, respectively, and an inlet 31 and an outlet 32 of the liquid cooling module 3 pass through the first groove 15 and the second groove 16, respectively. As such, it prevents the liquid cooling module 3 from sliding out of the tray 1.

In an embodiment, the tray 1 includes at least one rib 17 disposed on the bottom portion of the tray 1 and configured to be inserted into the at least one heat dissipation space of the liquid cooling module 3. The at least one rib 17 is configured to compensate the altitudes of the heat generating components E1 to E4 in the second direction Z, such that the altitudes of all the heat generating components E1–E8 are aligned in the second direction Z. Understandably, the rib 17, the first groove 15 and the second groove 16 can function as positioning structures to facilitate mounting of the liquid cooling module 3 within the tray 1. Furthermore, the configuration that each of the heat generating components E1 to E8 is inserted into a corresponding one of the heat dissipation spaces of the liquid cooling module 3 facilitates assembly and enhances structural robustness.

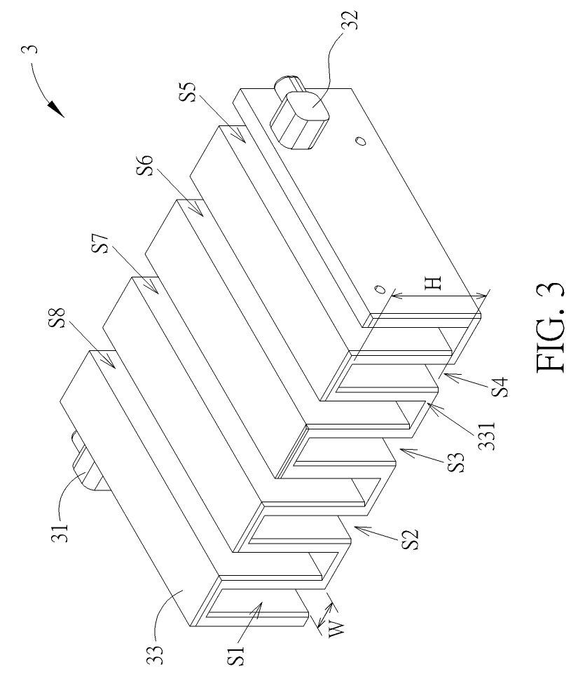

Please refer to FIG. 3, which is a perspective diagram of the liquid cooling module 3 according to the embodiment of the present invention. The liquid cooling module 3 includes the inlet 31, the outlet 32 and a casing 33. The inlet 31 is for inputting liquid coolant. The outlet 32 is for outputting the liquid coolant. The liquid coolant can flow into the casing 33 through the inlet 31 and flow out of the casing 33 through the outlet 32. Understandably, the casing 33 can contact the heat generating components E1 to E8 (which are shown in FIG. 1 and FIG. 2) directly or indirectly, so as to form a heat conducting interface for allowing the liquid coolant flowing inside the casing 33 to carry away heat transferred from the heat generating components E1 to E8. A cavity 331 of the casing 33 generally corresponds to an outer profile of the casing 33 and is formed in a meandering shape. The cavity 331 communicates with the inlet 31 and the outlet 32 for allowing the liquid coolant to flow therethrough. In practical implementations, the inlet 31 and the outlet 32 can connect to blind mate quick connectors through which connected to flexible hoses or manifolds, which is not limited thereto.

The casing 33 of the liquid cooling module 3 is formed in a meandering shape, so as to define heat dissipation spaces S1 to S8 external to the casing 33 for respectively accommodating the heat generating components E1 to E8, thereby improving space utilization and equipment density. It should be noticed that a dimension (e.g., a width W or a height H) of each of the heat dissipation spaces S1 to S8 can be designed based on the standard specifications of the heat generating components E1 to E8, thereby enabling compatibility. For example, E1.S refers to a form factor within the Enterprise & Datacenter SSD Form Factor (EDSFF) standards, where the solid-state drive can have a width of either 5.9 millimeters or 9.5 millimeters. If the widths W of the heat dissipation spaces S1 to S8 are set to 5.9 millimeters or 9.5 millimeters plus tolerance, the liquid cooling module 3 is compatible with solid-state drives conforming to the E1.S specification.

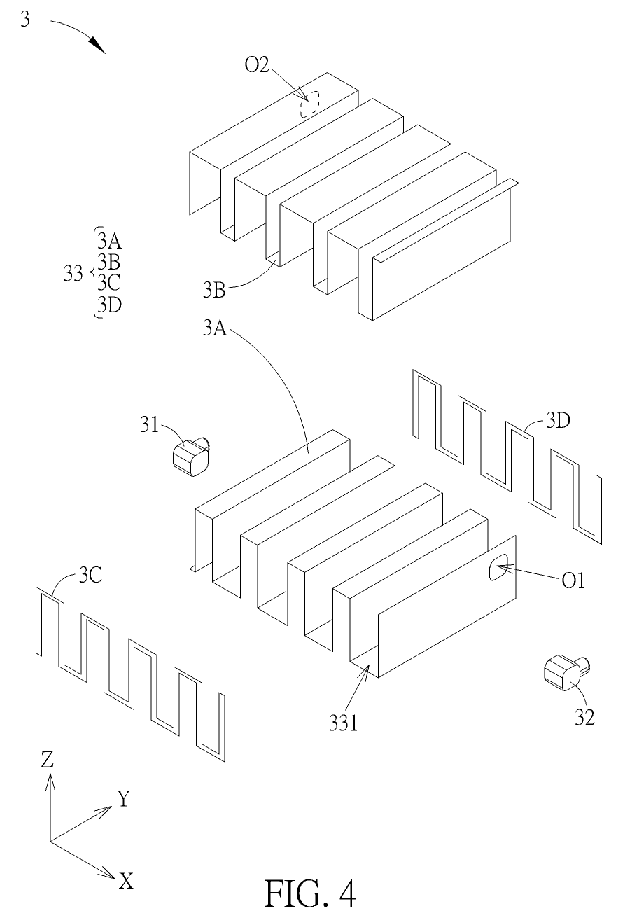

Please refer to FIG. 4, which is an exploded diagram of the liquid cooling module 3 according to the embodiment of the present invention. The casing 33 includes a first sub-casing 3A and a second sub-casing 3B. The first sub-casing 3A and the second sub-casing 3B are connected to each other to jointly define the cavity 331 within the casing 33. Both the first sub-casing 3A and the second sub-casing 3B are formed in meandering shapes, so as to define the heat dissipation spaces S1 to S8 external to the casing 33 for accommodating the heat generating components E1 to E8, respectively.

The casing 33 further includes a first side wall 3C and a second side wall 3D. The first side wall 3C is connected to a first side (e.g., a front side) of the first sub-casing 3A and a first side (e.g., a front side) of the second sub-casing 3B, and the first side wall 3C is formed in a meandering shape and extends along the first direction X. The second side wall 3D is connected to a second side (e.g., a rear side) of the first sub-casing 3A and a second side (e.g., a rear side) of the second sub-casing 3B, and the second side wall 3D is formed in a meandering shape and extends along the first direction X. Thus, the first sub-casing 3A and the second sub-casing 3B are connected to each other. The first side wall 3C is parallel to the second side wall 3D and an X-Z plane. In an embodiment, the first sub-casing 3A, the first side wall 3C and the second side wall 3D are integrally formed as a one-piece structure, and the one-piece structure is connected to the second sub-casing 3B by welding. In another embodiment, the casing 33 can be integrally formed as a one-piece structure by using 3D printing technology. Alternatively, the first sub-casing 3A, the second sub-casing 3B, the first side wall 3C, and the second side wall 3D can be manufactured separately and then joined together by welding.

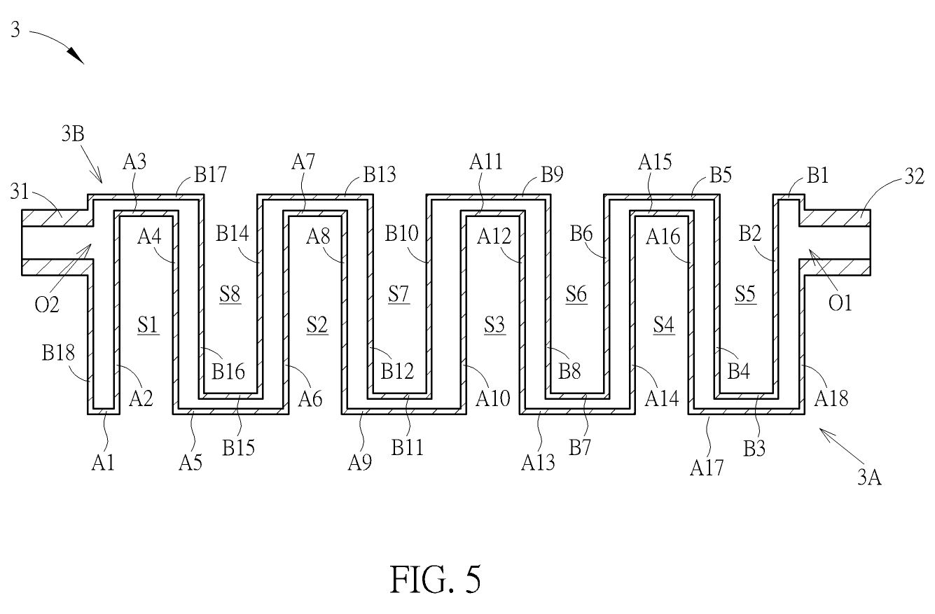

Please refer to FIG. 5, which is a sectional diagram of the liquid cooling module 3 according to the embodiment of the present invention. The first sub-casing 3A includes M walls, and the M walls of the first sub-casing 3A are configured to define N heat dissipation spaces. Specifically, a (4*i-2)-th wall, a (4*i-1)-th wall, and a (4*i)-th wall of the M walls of the first sub-casing 3A jointly define an i-th heat dissipation space external to the casing 33, where 1≤i≤N, M=4*N+2, and i, M, and N are natural numbers. For example, given that N=4, M=4*4+2=18, the first sub-casing 3A includes eighteen walls A1 to A18, and 1≤i≤4. When i=1, the walls A2, A3, A4 jointly define a first heat dissipation space S1; when i=2, the walls A6, A7, A8 jointly define a second heat dissipation space S2; when i=3, the walls A10, A11, A12 jointly define a third heat dissipation space S3; and, when i=4, the walls A14, A15, A16 jointly define a fourth heat dissipation space S4.

A plurality of odd-numbered walls of the M walls of the first sub-casing 3A are arranged in parallel. A plurality of even-numbered walls of the M walls of the first sub-casing 3A are arranged in parallel, and at least one of the plurality of odd-numbered walls is perpendicularly connected between corresponding two of the plurality of even-numbered walls. For example, as for the walls A1 to A18 of the first sub-casing 3A, the odd-numbered walls A1, A3, A5, A7, A9, A11, A13, A15 and A17 are arranged in parallel. The even-numbered walls A2, A4, A6, A8, A10, A12, A14, A16 and A18 are arranged in parallel. The odd-numbered wall A1 is perpendicularly connected to the even-numbered wall A2. The odd-numbered wall A3 is perpendicularly connected between the even-numbered walls A2 and A4. The odd-numbered wall A5 is perpendicularly connected between the even-numbered walls A4 and A6. The same pattern applies to the remaining walls.

As for the walls A1 to A18 of the first sub-casing 3A, the odd-numbered walls A1, A3, A5, A7, A9, A11, A13, A15 and A17 extend along the first direction X, and the even-numbered walls A2, A4, A6, A8, A10, A12, A14, A16 and A18 extend along the second direction Z. The heat generating components E1 to E4 are configured to be inserted into the heat dissipation spaces S1 to S4 along the third direction Y, respectively, and the first direction X, the second direction Z and the third direction Y are perpendicular to one another.

Given that N=4 and 1≤i≤4, an i-th heat generating component of the heat generating components E1 to E4 includes a first surface, a second surface and a third surface. The first surface is configured to contact an (4*i-2)-th wall. The second surface is configured to contact an (4*i)-th wall. The third surface is perpendicular to and connected between the first surface and the second surface. For example, if i=1, when the heat generating component E1 is inserted into the heat dissipation space S1, the first surface and the second surface of the heat generating component E1 contact the second wall A2 and the fourth wall A4, respectively. If i=2, when the heat generating component E2 is inserted into the heat dissipation space S2, the first surface and the second surface of the heat generating component E2 contact the sixth wall A6 and the eighth wall A8, respectively. If i=3, , when the heat generating component E3 is inserted into the heat dissipation space S3, the first surface and the second surface of the heat generating component E3 contact the tenth wall A10 and the twelfth wall A12, respectively. If i=4, when the heat generating component E4 is inserted into the heat dissipation space S4, the first surface and the second surface of the heat generating component E4 contact the fourteenth wall A14 and the sixteenth wall A16, respectively.

The second sub-casing 3B and the first sub-casing 3A are inversely symmetrical to each other, i.e., the shape and the configuration of the second sub-casing 3B are mirrored images of those of the first sub-casing 3A, and the second sub-casing 3B and the first sub-casing 3A are connected end to end but oriented in opposite directions. Specifically, the first wall A1 of the first sub-casing 3A is connected to a M-th wall B18 of the second sub-casing 3B, and the M-th wall A18 of the first sub-casing 3A is connected to a first wall B1 of the second sub-casing 3B.

A number of the at least one heat dissipation space is not less than 2*N. The second sub-casing 3B includes M walls. A (4*i-2)-th wall, a (4*i-1)-th wall, and a (4*i)-th wall of the M walls of the second sub-casing 3B jointly define an (N+i)-th heat dissipation space external to the casing 33, where 1≤i≤N, M=4*N+2, and i, M, and N are natural numbers. For example, given that N=4, M=4*4+2=18, the second sub-casing 3B includes eighteen walls B1 to B18, and 1≤i≤4. When i=1, the walls B2, B3, B4 jointly define the fifth heat dissipation space S5; when i=2, the walls B6, B7, B8 jointly define the sixth heat dissipation space S6; when i=3, the walls B10, B11, B12 jointly define the seventh heat dissipation space S7; when i=4, the walls B14, B15, B16 jointly define the eighth heat dissipation space S8.

A plurality of odd-numbered walls of the M walls of the second sub-casing 3B are arranged in parallel. A plurality of even-numbered walls of the M walls of the second sub-casing 3B are arranged in parallel, and at least one of the plurality of odd-numbered walls is perpendicularly connected between corresponding two of the plurality of even-numbered walls. For example, as for the walls B1 to B18 of the second sub-casing 3B, the odd-numbered walls B1, B3, B5, B7, B9, B11, B13, B15 and B17 are arranged in parallel. The even-numbered walls B2, B4, B6, B8, B10, B12, B14, B16 and B18 are arranged in parallel. The odd-numbered wall B1 is perpendicularly connected to the even-numbered wall B2. The odd-numbered wall B3 is perpendicularly connected between the even-numbered walls B2 and B4. The odd-numbered wall B5 is perpendicularly connected between the even-numbered walls B4 and B6. The same pattern applies to the remaining walls.

As for the walls B1 to B18 of the second sub-casing 3B, the odd-numbered walls B1, B3, B5, B7, B9, B11, B13, B15 and B17 extend along the first direction X, and the even-numbered walls B2, B4, B6, B8, B10, B12, B14, B16 and B18 extend along the second direction Z. The heat generating components E5 to E8 are configured to be inserted into the heat dissipation spaces S5 to S8 along the third direction Y, respectively, and the first direction X, the second direction Z and the third direction Y are perpendicular to one another.

Given that N=4 and 1≤i≤4, an (4+i)-th heat generating component of the heat generating components E5 to E8 includes a first surface, a second surface and a third surface. The first surface is configured to contact an (4*i-2)-th wall. The second surface is configured to contact an (4*i)-th wall. The third surface is perpendicular to and connected between the first surface and the second surface. For example, if i=1, when the heat generating component E5 is inserted into the heat dissipation space S5, the first surface and the second surface of the heat generating component E5 contact the second wall B2 and the fourth wall B4, respectively. If i=2, when the heat generating component E6 is inserted into the heat dissipation space S6, the first surface and the second surface of the heat generating component E6 contact the sixth wall B6 and the eighth wall B8, respectively. If i=3, when the heat generating component E7 is inserted into the heat dissipation space S7, the first surface and the second surface of the heat generating component E7 contact the tenth wall B10 and the twelfth wall B12, respectively. If i=4, when the heat generating component E8 is inserted into the heat dissipation space S8, the first surface and the second surface of the heat generating component E8 contact the fourteenth wall B14 and the sixteenth wall B16, respectively.

Additionally, a first opening O1 is formed on the M-th wall A18 of the first sub-casing 3A, and the outlet 32 is connected to the first opening O1. A second opening O2 is formed on the M-th wall B18 of the second sub-casing 3B, and the inlet 31 is connected to the second opening O2. In some embodiments, the positions, the shapes and the numbers of the first opening O1 and the second opening O2 can be designed based on the positions, the shapes and the numbers of the inlet 31 and the outlet 32, which is not limited to this embodiment.

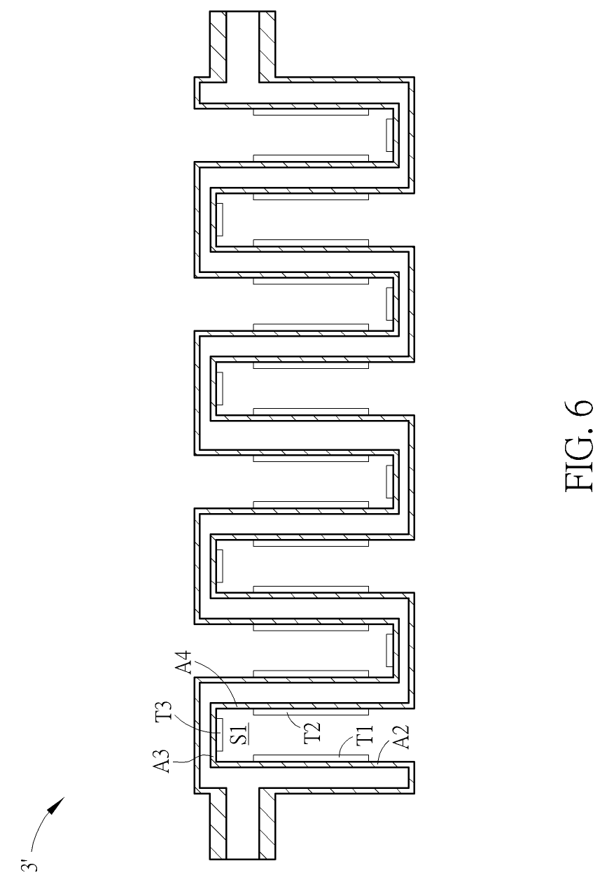

Please refer to FIG. 6, which is a sectional diagram of a liquid cooling module 3’ according to another embodiment of the present invention. The liquid cooling module 3’ further includes a first heat dissipating pad T1 and a second heat dissipating pad T2. The first heat dissipating pad T1 is disposed between the first surface and the (4*i-2)-th wall and contacts both the first surface and the (4*i-2)-th wall. The second heat dissipating pad T2 is disposed between the second surface and the (4*i)-th wall and contacts both the second surface and the (4*i)-th wall. For example, when i=1, the first heat dissipating pad T1 is disposed between the first surface of the heat generating component E1 and the second wall A2 of the first sub-casing 3A, and the second heat dissipating pad T2 is disposed between the second surface of the heat generating component E1 and the fourth wall A4 of the first sub-casing 3A, such that the heat generating component E1 contacts the liquid cooling module 3’ via the first heat dissipating pad T1 and the second heat dissipating pad T2. The same pattern applies to the remaining heat generating components E2 to E8.

In an embodiment, the liquid cooling module 3’ further includes a third heat dissipating pad T3 disposed between the third surface and the (4*i-1)-th wall and contacting both the third surface and the (4*i-1)-th wall. For example, when i=1, the third heat dissipating pad T3 is disposed between the third surface of the heat generating component E1 and the third wall A3 of the first sub-casing 3A, such that the heat generating component E1 contacts the liquid cooling module 3’ via the third heat dissipating pad T3. The same pattern applies to the remaining heat generating components E2 to E8. Understandably, in the embodiment of FIG. 6, the heat generating components E1 to E8 contact the liquid cooling module 3’ indirectly via the heat dissipating pad T1, T2 and T3. While in the embodiment of FIG. 5, the heat generating components E1 to E8 contact the liquid cooling module 3 directly. Noticeably, each heat dissipation space provides three (directly or indirectly) contact surfaces for contacting the corresponding heat generating component, thereby offering increased heat dissipation area and improved heat dissipation efficiency.

In addition, an assembly method for the data storage assembly 1000 includes the following steps.

Step A: Place the third bracket 13 adjacent to the third side (e.g., the left side) of the liquid cooling module 3, with the two ends of the third bracket 13 fixed onto the lateral wall and the bottom portion of the tray 1.

Step B: Place the fourth bracket 14 adjacent to the fourth side (e.g., the right side) of the liquid cooling module 3, with the two ends of the fourth bracket 14 fixed onto the other lateral wall and the bottom portion of the tray 1.

Step C: Place the liquid cooling module 3 into the tray 1; optionally, before Step C, the at least one rib 17 is disposed on the bottom portion of the tray 1.

Step D: Place the docking board 5 adjacent to the second side (e.g., the rear side) of the liquid cooling module 3.

Step E: Place the first bracket 4 adjacent to the first side (e.g., the front side) of the liquid cooling module 3, with the two ends of the first bracket 4 fixed onto the third bracket 13 and the fourth bracket 14.

Step F: Place the second bracket 6 adjacent to the second side (e.g., the rear side) of the liquid cooling module 3, with the two ends of the second bracket 6 fixed onto the third bracket 13 and the fourth bracket 14.

Step G: Insert the heat generating components E1 to E8 into the heat dissipation spaces S1 to S8, respectively.

In summary, the liquid cooling module and the related data storage assembly achieve the following technical effects: (1) the casing of the liquid cooling module is formed in a meandering shape, so as to define the at least one heat dissipation space external to the casing for accommodating the at least one heat generating component, thereby improving space utilization and equipment density; (2) each heat dissipation space provides multiple contact surfaces for the corresponding heat generating component, thereby offering increased heat dissipation area and improved heat dissipation efficiency; (3) each heat generating component is inserted into the corresponding heat dissipation space, thereby facilitating assembly and enhancing structural robustness; and (4) the dimension of the heat dissipation space can be designed based on the standard specifications of the heat generating component, thereby enabling interchangeability and compatibility.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A liquid cooling module for cooling at least one heat generating component, the liquid cooling module comprising:
an inlet for inputting a liquid coolant;
an outlet for outputting the liquid coolant; and
a casing comprising a first sub-casing and a second sub-casing, the first sub-casing and the second sub-casing being connected to each other to jointly define a cavity;
wherein the cavity communicates with the inlet and the outlet for allowing the liquid coolant to flow therethrough, and the cavity is formed in a meandering shape;
wherein both the first sub-casing and the second sub-casing are formed in meandering shapes, so as to define at least one heat dissipation space external to the casing for accommodating the at least one heat generating component.

2. The liquid cooling module of claim 1, wherein the first sub-casing comprises M walls, and a (4*i-2)-th wall, a (4*i-1)-th wall, and a (4*i)-th wall of the M walls jointly define an i-th heat dissipation space external to the casing, where 1≤i≤N, M=4*N+2, and i, M, and N are natural numbers.

3. The liquid cooling module of claim 2, wherein a plurality of odd-numbered walls of the M walls of the first sub-casing are arranged in parallel, a plurality of even-numbered walls of the M walls of the first sub-casing are arranged in parallel, and at least one of the plurality of odd-numbered walls is perpendicularly connected between corresponding two of the plurality of even-numbered walls.

4. The liquid cooling module of claim 2, wherein an i-th heat generating component of the at least one heat generating component comprises:
a first surface configured to directly or indirectly contact the (4*i-2)-th wall;
a second surface parallel to the first surface and configured to directly or indirectly contact the (4*i)-th wall; and
a third surface perpendicular to the first surface and the second surface and connected between the first surface and the second surface.

5. The liquid cooling module of claim 4, further comprising:
a first heat dissipating pad disposed between the first surface and the (4*i-2)-th wall and contacting both the first surface and the (4*i-2)-th wall; and
a second heat dissipating pad disposed between the second surface and the (4*i)-th wall and contacting both the second surface and the (4*i)-th wall.

6. The liquid cooling module of claim 4, further comprising:
a third heat dissipating pad disposed between the third surface and the (4*i-1)-th wall and contacting both the third surface and the (4*i-1)-th wall.

7. The liquid cooling module of claim 2, wherein the second sub-casing and the first sub-casing are inversely symmetrical to each other, each of the first sub-casing and the second sub-casing comprises a first wall to a M-th wall, the first wall of the first sub-casing is connected to the M-th wall of the second sub-casing, and the M-th wall of the first sub-casing is connected to the first wall of the second sub-casing.

8. The liquid cooling module of claim 7, wherein a number of the at least one heat dissipation space is not less than 2*N, and the (4*i-2)-th wall, the (4*i-1)-th wall, and the (4*i)-th wall of M walls of the second sub-casing jointly define an (N+i)-th heat dissipation space external to the casing.

9. The liquid cooling module of claim 7, wherein:
a first opening is formed on the M-th wall of the first sub-casing, the outlet is connected to the first opening; and
a second opening is formed on the M-th wall of the second sub-casing, the inlet is connected to the second opening.

10. The liquid cooling module of claim 2, wherein a plurality of odd-numbered walls of the M walls of the first sub-casing extend along a first direction, a plurality of even-numbered walls of the M walls of the first sub-casing extend along a second direction, the at least one heat generating component is inserted into the at least one heat dissipation space along a third direction, and the first direction, the second direction and third direction are perpendicular to one another.

11. The liquid cooling module of claim 10, wherein the casing further comprises:
a first side wall connected to a first side of the first sub-casing and a first side of the second sub-casing, the first side wall being formed in a meandering shape and extending along the first direction; and
a second side wall connected to a second side of the first sub-casing and a second side of the second sub-casing, the second side wall being formed in a meandering shape and extending along the first direction.

12. A data storage assembly comprising:
a tray;
at least one heat generating component; and
the liquid cooling module of claim 1;
wherein the liquid cooling module is disposed within the tray and configured to cool the at least one heat generating component.

13. The data storage assembly of claim 12, further comprising:
a first bracket disposed adjacent to a first side of the liquid cooling module, two ends of the first bracket being connected to the tray to secure the liquid cooling module and the at least one heat generating component to the tray;
a docking board disposed adjacent to a second side of the liquid cooling module opposite the first side of the liquid cooling module, the docking board being connected to the at least one heat generating component; and
a second bracket disposed adjacent to the second side of the liquid cooling module, two ends of the second bracket being connected to the tray to secure the liquid cooling module and the docking board to the tray.

14. The data storage assembly of claim 13, wherein at least one engaging slot is formed on the first bracket for engaging with at least one hook of the at least one heat generating component.

15. The data storage assembly of claim 13, further comprising:
a third bracket disposed adjacent to a third side of the liquid cooling module, an end of the third bracket being fixed onto a side wall of the tray, another end of the third bracket being fixed onto a bottom portion of the tray; and
a fourth bracket disposed adjacent to a fourth side of the liquid cooling module, an end of the fourth bracket being fixed onto another side wall of the tray, another end of the fourth bracket being fixed onto the bottom portion of the tray;
wherein one of the two ends of the first bracket and one of the two ends of the second bracket are fixed onto the third bracket, and another of the two ends of the first bracket and another of the two ends of the second bracket are fixed onto the fourth bracket.

16. The data storage assembly of claim 15, wherein a first groove is formed on the third bracket, the inlet of the liquid cooling module passes through the first groove, a second groove is formed on the fourth bracket, and the outlet of the liquid cooling module passes through the second groove.

17. The data storage assembly of claim 12, wherein the tray comprises at least one rib disposed on a bottom portion of the tray and configured to be inserted into the at least one heat dissipation space.
